(19) United States
(12) Patent Application Publication
(10) Pub. No.: US 2026/0101648 A1
(43) Pub. Date: Apr. 9, 2026

(54) DISPLAY DEVICE, METHOD OF MANUFACTURING THE SAME, AND ELECTRONIC DEVICE INCLUDING THE SAME

(71) Applicant: Samsung Display Co., Ltd., Yongin-si (KR)

(72) Inventor: Chun Gi YOU, Yongin-si (KR)

(21) Appl. No.: 19/265,416

(22) Filed: Jul. 10, 2025

(30) Foreign Application Priority Data
Oct. 4, 2024 (KR) 10-2024-0135033

(51) Int. Cl. H10K 59/124; H10K 59/12; H10K 59/80

(52) U.S. Cl. CPC H10K 59/124; H10K 59/1201; H10K 59/879

(57) ABSTRACT

A display device may include a substrate, light emitting elements on the substrate and at a display area, an alignment key on the substrate and at a portion of an alignment area of a non-display area enclosing the display area, and a capping layer covering an entirety of the alignment area and including an inorganic material.

### CROSS-REFERENCE TO RELATED APPLICATION

The present application claims priority to and the benefit of Korean Patent Application No. 10-2024-0135033, filed on Oct. 4, 2024, in the Korean Intellectual Property Office, the entire disclosure of which is incorporated herein by reference.

### BACKGROUND

### 1. Field

One or more suitable embodiments of the present disclosure relate to a display device. For example, one or more suitable embodiments of the present disclosure relate to a display device, a method of manufacturing the display device, and an electronic device including the display device.

### 2. Description of the Related Art

As interest in information displays develops, research and developments on alignment keys for aligning components during a process of manufacturing a display device have been continuously conducted.

The information disclosed in this background section is provided to enhance the understanding of the background of the described technology. It may contain information that does not form part of the prior art suitable to a person of ordinary skill in the art.

### SUMMARY

One or more suitable embodiments of the present disclosure are directed toward a display device with improved or enhanced reliability.

One or more suitable embodiments of the present disclosure are directed toward a method of manufacturing the display device.

The aspects of the present disclosure are not limited to the above-stated aspect, and those skilled in the art will understand other not mentioned aspects from the accompanying claims.

One or more embodiments of the present disclosure may provide a display device including a substrate, light emitting elements arranged on the substrate and positioned at a display area, an alignment key arranged on the substrate and positioned at a portion of an alignment area of a non-display area enclosing the display area, and a capping layer covering an entirety of the alignment area and including an inorganic material.

In one or more embodiments, the display device may further include a base layer arranged between the substrate and the capping layer and provided in the entirety of the alignment area other than the alignment key.

In one or more embodiments, the base layer may include a first base layer arranged on the substrate, and a second base layer arranged between the first base layer and the capping layer. A reflectance of the first base layer may be higher than a reflectance of the second base layer.

In one or more embodiments, the first base layer may include aluminum. The second base layer may include titanium nitride.

In one or more embodiments, the capping layer may include aluminum oxide.

In one or more embodiments, the capping layer may include a first capping layer arranged on the base layer, a second capping layer arranged on the first capping layer, and a third capping layer arranged on the second capping layer.

In one or more embodiments, the first capping layer may include aluminum oxide. The second capping layer may include acrylic resin. The third capping layer may include acrylic resin.

In one or more embodiments, the display device may further include an encapsulation thin-film arranged on the light emitting elements in the display area, an adhesive layer arranged on the encapsulation thin-film in the display area, a color filter layer arranged on the adhesive layer in the display area, and a lens layer arranged on the color filter layer in the display area.

In one or more embodiments, the first capping layer may include a material substantially identical to the encapsulation thin-film. The second capping layer may include a material substantially identical to the adhesive layer. The third capping layer may include a material substantially identical to the lens layer.

In one or more embodiments, the alignment key may protrude from an upper surface of the base layer.

In one or more embodiments, the alignment key may include an inorganic material.

One or more embodiments of the present disclosure may provide a method of manufacturing a display device, including forming (e.g., applying) light emitting elements on a substrate at a display area, forming (e.g., applying) an alignment key on the substrate at a portion of an alignment area of a non-display area enclosing the display area, and forming (e.g., applying) a capping layer covering an entirety of the alignment area and including an inorganic material.

In one or more embodiments, the method may further include, before the forming of the alignment key, forming (e.g., applying) a base layer on the substrate and including an opening defined in the portion of the alignment area.

In one or more embodiments, the alignment key may be formed at the opening, and protrude from an upper surface of the base layer.

In one or more embodiments, the base layer may include a first base layer and a second base layer. The forming of the base layer may include forming (e.g., applying) a first base layer on the substrate, forming (e.g., applying) a second base layer on the first base layer, and forming the opening by patterning a portion of the first base layer and a portion of the second base layer. A reflectance of a material forming the first base layer may be higher than a reflectance of a material forming the second base layer.

In one or more embodiments, the first base layer may include (e.g., be formed of) aluminum. The second base layer may include (e.g., be formed of) titanium nitride.

In one or more embodiments, the capping layer may include aluminum oxide.

In one or more embodiments, the capping layer may include first to third capping layers. Forming of the capping layer may include forming the first capping layer on the base layer and including aluminum oxide; forming the second capping layer on the first capping layer and including acrylic resin; and forming the third capping layer on the second capping layer and including acrylic resin.

In one or more embodiments, the method may further include, after the forming of the light emitting elements, forming (e.g., applying) an encapsulation thin-film on the light emitting elements at the display area, forming (e.g., applying) an adhesive layer on the encapsulation thin-film at the display area, forming (e.g., applying) a color filter layer on the adhesive layer at the display area, and forming (e.g., applying) a lens layer on the color filter layer at the display area.

In one or more embodiments, the first capping layer may be formed concurrently (e.g., simultaneously) with the encapsulation thin-film. The second capping layer may be formed concurrently (e.g., simultaneously) with the adhesive layer. The third capping layer may be formed concurrently (e.g., simultaneously) with the lens layer.

One or more embodiments of the present disclosure may provide an electronic device including a processor to provide input image data, and a display device to display an image based on the input image data. The display device may include a substrate, light emitting elements arranged on the substrate and positioned at a display area, an alignment key arranged on the substrate and positioned at a portion of an alignment area of a non-display area enclosing the display area, and a capping layer covering an entirety of the alignment area and including an inorganic material.

In one or more embodiments, the electronic device may include a mobile phone, a smartphone, a tablet personal computer (PC), a mobile communication terminal, an electronic organizer, an electronic book, a portable multimedia player (PMP), a navigation system, a navigation device, an ultra-mobile PC (UMPC), a television, a laptop, a monitor, an electric vehicle, a billboard, an Internet of Things (IoT) device, a smartwatch, a watch phone, or a head-mounted display (HMD).

The present disclosure provides a display device with enhanced reliability and a method for its manufacturing. The display device may include a substrate, light-emitting elements positioned in a display area, and an alignment key located in a non-display area surrounding the display area. This alignment key may be covered by a capping layer made of inorganic material, which enhances the display device's durability. Additionally, the display device may feature a base layer between the substrate and the capping layer, including a first base layer with higher reflectance and a second base layer with lower reflectance. The method of manufacturing the display device may involve forming light-emitting elements on the substrate, creating an alignment key in the non-display area, and applying a capping layer over the alignment area. The process may also include forming a base layer before the forming of the alignment key, with the base layer composed of two sub-layers. The display device may be integrated into various electronic devices, such as smartphones, tablets, and televisions, providing improved performance and reliability.

Details of one or more suitable embodiments are included in the detailed descriptions and drawings.

### BRIEF DESCRIPTION OF THE DRAWINGS

FIG. 1 is a block diagram illustrating one or more embodiments of a display device.

FIG. 2 is a block diagram illustrating one or more embodiments of a sub-pixel of FIG. 1.

FIG. 3 is a circuit diagram illustrating one or more embodiments of the sub-pixel of FIG. 2.

FIG. 4 is a plan view illustrating one or more embodiments of a display panel of FIG. 1.

FIG. 5 is an exploded perspective view illustrating a portion of a display area of the display panel of FIG. 4.

FIG. 6 is a plan view illustrating one or more embodiments of a first pixel of FIG. 5.

FIG. 7 is a sectional view taken along the line I-I′ of FIG. 6 in accordance with one or more embodiments of the present disclosure.

FIG. 8 is an enlarged plan view illustrating an alignment area of FIG. 4.

FIG. 9 is a sectional view taken along the line II-II′ of FIG. 8.

FIG. 10 is an enlarged sectional view illustrating a capping layer of FIG. 9.

FIGS. 11-16 are diagrams illustrating operations (e.g., steps, tasks, and/or acts) of a method of manufacturing the display device in accordance with one or more embodiments of the present disclosure.

FIG. 17 is a block diagram of an electronic device according to one or more embodiments.

FIG. 18 shows schematic views of one or more suitable embodiments of an electronic device.

### DETAILED DESCRIPTION

As the present disclosure allows for one or more suitable changes and numerous embodiments, particular embodiments will be illustrated in the drawings and described in more detail in the written description. However, this is not intended to limit the present disclosure to particular modes of practice, and it is to be appreciated that all changes, equivalents, and substitutes that do not depart from the spirit and technical scope of the present disclosure are encompassed in the present disclosure.

Throughout the disclosure, like reference numerals refer to like parts throughout the one or more suitable drawings and embodiments of the present disclosure. The sizes of elements in the accompanying drawings may be exaggerated for clarity of illustration. It will be understood that, although the terms “first”, “second”, and/or the like. may be utilized herein to describe one or more suitable elements, these elements should not be limited by these terms. These terms are only utilized to distinguish one element from another element. For instance, a first element discussed could be termed a second element without departing from the teachings of the present disclosure. Similarly, the second element could also be termed the first element.

It will be further understood that the terms “comprise/comprises/comprising”, “include/includes/including”, “have/has/having”, and/or the like. if (e.g., when) utilized in this specification, specify the presence of stated features, integers, steps, operations, elements, components, and/and/or one or more (e.g., any suitable) combinations of them but do not preclude the presence or addition of one or more other features, integers, steps, operations, elements, components, and/and/or one or more (e.g., any suitable) combinations thereof. Additionally, the terms “comprise/comprises/comprising,” “include/includes/including,” “have/has/having” or similar terms include or support the terms “consisting of” and “consisting essentially of,” indicating the presence of stated features, integers, steps, operations, elements, and/or components, without or essentially without the presence of other features, integers, steps, operations, elements, components, and/or groups thereof. In case that a first part such as a layer, a film, a region, or a plate is arranged on a second part, the first part may be not only directly on the second part but a third part may intervene between them. In the present specification, in case that it is expressed that a first part such as a layer, a film, a region, or a plate is formed on a second part, the surface of the second part on which the first part is formed is not limited to an upper surface of the second part but may include other surfaces such as a side surface or a lower surface of the second part. To the contrary, in case that a first part such as a layer, a film, a region, or a plate is under a second part, the first part may be not only directly under the second part but a third part may intervene between them.

While such terms as “first” and “second” may be utilized to describe one or more suitable components, such components must not be limited to the above terms. The above terms are utilized to distinguish one component from another.

The singular forms “a,” “an,” and “the” as utilized herein are intended to include the plural forms as well unless the context clearly indicates otherwise.

As utilized herein, the term “and/or” includes any and all combinations of one or more of the associated listed items. Throughout the disclosure, the expression “at least one of a, b or c” indicates only a, only b, only c, both (e.g., simultaneously) a and b, both (e.g., simultaneously) a and c, both (e.g., simultaneously) b and c, all of a, b, and c, or variations thereof.

It will also be understood that if (e.g., when) an element or layer is referred to as being “on,” “connected to”, “coupled to”, or “adjacent to” another element, layer, or substrate, it can be directly on, connected to, coupled to, or adjacent to the other element, layer, or substrate, or one or more intervening elements, layers, or substrates may also be present. In contrast, when an element or layer is referred to as being “directly on,” “directly connected to”, “directly coupled to”, or “immediately adjacent to” another element or layer, there are no intervening elements or layers present.

The first direction DR1, the second direction DR2, and the third direction DR3 are not limited to directions corresponding to three axes of the rectangular coordinate system, and may be interpreted in a broader sense. For example, the first direction DR1, the second direction DR2, and the third direction DR3 may be normal (e.g., perpendicular) to one another, or may represent different directions that are not normal (e.g., perpendicular) to one another.

Embodiments and desired or required details of the present disclosure are described with reference to the accompanying drawings in order to describe the present disclosure in more detail so that those having ordinary knowledge in the technical field to which the present disclosure pertains may suitably practice the present disclosure, where like reference numerals refer to like elements throughout, and duplicative descriptions thereof may not be provided, and a repeated description thereof is omitted. Sizes of elements in the drawings may be exaggerated or reduced for convenience of explanation. In some embodiments, the size and thickness of each element shown in the drawings are arbitrarily represented for convenience of description, and thus, the disclosure is not necessarily limited thereto. The same reference numeral indicates the same component throughout the specification. Furthermore, a singular form may include a plural form as long as it is not specifically mentioned in a sentence.

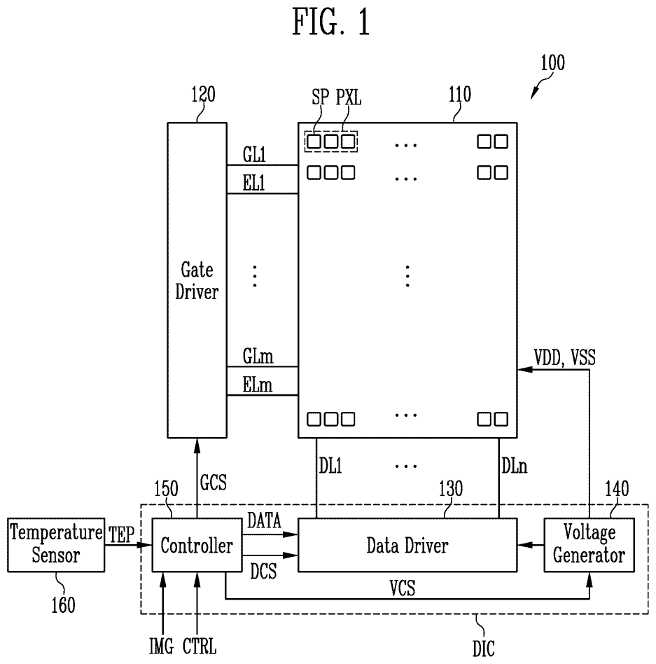

FIG. 1 is a block diagram illustrating one or more embodiments of a display device.

Referring to FIG. 1, the display device 100 may include a display panel 110, a gate driver 120, a data driver 130, a voltage generator 140, and a controller 150.

The display panel 110 may include sub-pixels SP. The sub-pixels SP may be connected to the gate driver 120 through first to m-th gate lines GL1 to GLm. The sub-pixels SP may be connected to the data driver 130 through first to n-th data lines DL1 to DLn, where m and n are positive integers greater than 1.

Each of the sub-pixels SP may include at least one light emitting element configured to generate light. Accordingly, each of the sub-pixels SP may generate light in a specific color, such as red, green, blue, cyan, magenta, and/or yellow. Two or more sub-pixels SP among the sub-pixels SP may form a pixel PXL. For example, as illustrated in FIG. 1, three sub-pixels SP may form one pixel PXL.

The gate driver 120 may be connected to the sub-pixels SP arranged in a row direction through the first to m-th gate lines GL1 to GLm. The gate driver 120 may output gate signals to the first to m-th gate lines GL1 to GLm in response to a gate control signal GCS. In one or more embodiments, the gate control signal GCS may include a start signal instructing each frame to start, a horizontal synchronization signal for outputting gg*ate signals in synchronization with a timing at which data signals are applied, and/or the like.

In one or more embodiments, first to m-th emission control lines EL1 to ELm may be provided, which are connect to the sub-pixels SP arranged in the row direction. In this case, the gate driver 120 may include an emission control driver configured to control the first to m-th emission control lines EL1 to ELm. The emission control driver may operate under the control of the controller 150.

The gate driver 120 may be arranged on one side of the display panel 110. However, one or more embodiments are not limited to the aforementioned example. For example, the gate driver 120 may be divided into two or more drivers that are physically and/or logically distinguished from each other. The drivers may be arranged on a first side of the display panel 110 and a second side of the display panel 110 opposite to the first side. As such, the gate driver 120 may be arranged around the display panel 110 in one or more suitable configurations according to one or more embodiments.

The data driver 130 may be connected to sub-pixels SP arranged in a column direction through the first to n-th data lines DL1 to DLn. The data driver 130 may receive image data DATA and a data control signal DCS from the controller 150. The data driver 130 may operate in response to the data control signal DCS. In one or more embodiments, the data control signal DCS may include a source start pulse, a source shift clock, a source output enable signal, and/or the like.

The data driver 130 may apply, utilizing voltages from the voltage generator 140, data signals having grayscale voltages corresponding to the image data DATA to the first to n-th data lines DL1 to DLn. If (e.g., when) a gate signal is applied to each of the first to m-th gate lines GL1 to GLm, data signals corresponding to the image data DATA may be applied to the first to n-th data lines DL1 to DLn. Hence, the associated sub-pixels SP may generate light corresponding to the data signals. As a result, an image may be displayed on the display panel 110.

In one or more embodiments, the gate driver 120 and the data driver 130 may include complementary metal-oxide semiconductor (CMOS) circuit elements.

The voltage generator 140 may operate in response to a voltage control signal VCS provided from the controller 150. The voltage generator 140 is configured to generate a plurality of voltages and provide the generated voltages to components of the display device 100. For example, the voltage generator 140 may be configured to receive an input voltage from an external device provided outside the display device 100, adjust the received voltage, and regulate the adjusted voltage, thus generating a plurality of voltages.

The voltage generator 140 may generate a first power voltage VDD and a second power voltage VSS. The generated first and second power voltages VDD and VSS may be provided to the sub-pixels SP. The first power voltage VDD may have a relatively high voltage level. The second power voltage VSS may have a voltage level lower than the first power voltage VDD. In one or more embodiments, the first power voltage VDD and/or the second power voltage VSS may be provided by an external device of the display device 100.

In addition, the voltage generator 140 may generate one or more suitable voltages. For example, the voltage generator 140 may generate an initialization voltage to be applied to the sub-pixels SP. For example, during a sensing operation for sensing electrical characteristics of transistors and/or light emitting elements of the sub-pixels SP, a reference voltage may be applied to each of the first to n-th data lines DL1 to DLn. The voltage generator 140 may generate the reference voltage.

The controller 150 may control overall operations of the display device 100. The controller 150 may receive input image data IMG and a control signal CTRL for controlling an operation of displaying the input image data IMG from an external device. The controller 150 may provide a gate control signal GCS, a data control signal DCS, and/or a voltage control signal VCS, in response to the control signal CTRL.

The controller 150 may convert the input image data IMG to be suitable for the display device 100 and/or the display panel 110 and then output image data DATA. In one or more embodiments, the controller 150 may align the input image data IMG to be suitable for the sub-pixels SP on a row basis and then output the image data DATA.

Two or more components of the data driver 130, the voltage generator 140, and the controller 150 may be mounted on a single integrated circuit. As illustrated in FIG. 1, the data driver 130, the voltage generator 140, and the controller 150 may be included in a driver integrated circuit DIC. In this case, the data driver 130, the voltage generator 140, and the controller 150 may be components that are functionally separated from each other in the single driver integrated circuit DIC. In one or more embodiments, at least one of the data driver 130, the voltage generator 140, and/or the controller 150 may be provided as a component separate from the driver integrated circuit DIC.

The display device 100 may include at least one temperature sensor 160. The temperature sensor 160 is configured to sense a peripheral temperature and generate temperature data TEP indicating the sensed temperature (e.g., the peripheral temperature). In one or more embodiments, the temperature sensor 160 may be arranged adjacent to the display panel 110 and/or the driver integrated circuit DIC.

The controller 150 may control one or more suitable operations of the display device 100 in response to the temperature data TEP. In one or more embodiments, the controller 150 may adjust the luminance of an image outputted from the display panel 110 in response to the temperature data TEP. For example, the controller 150 may control components such as the data driver 130 and/or the voltage generator 140, thus adjusting data signals and the first and second power voltages VDD and VSS.

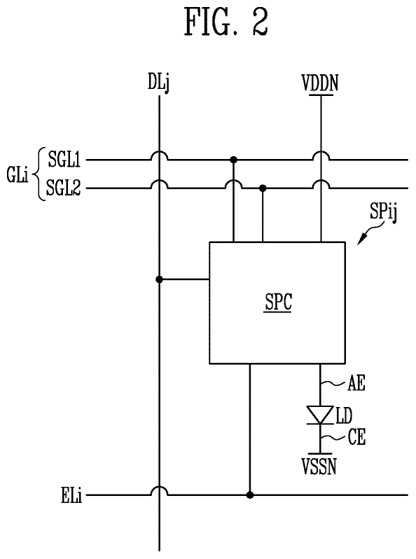

FIG. 2 is a block diagram illustrating one or more embodiments of the sub-pixel SP (e.g., any sub-pixel SP of the sub-pixels SP) of FIG. 1. In FIG. 2, a sub-pixel SPij is illustrated, arranged on an i-th row (where i is an integer equal to or greater than 1 and less than or equal to m) and a j-th column (where j is an integer equal to or greater than 1 and less than or equal to n) among the sub-pixels SP of FIG. 1.

Referring to FIG. 2, the sub-pixel SPij may include a sub-pixel circuit SPC and a light emitting element LD.

The light emitting element LD is connected between a first power voltage node VDDN and a second power voltage node VSSN. Here, the first power voltage node VDDN may be a node provided to transmit the first power voltage VDD of FIG. 1. The second power voltage node VSSN may be a node provided to transmit the second power voltage VSS of FIG. 1. 25 the first power voltage node VDDN through the sub-pixel circuit SPC. A cathode electrode CE of the light emitting element LD may be connected to the second power voltage node VSSN. For example, the anode electrode AE of the light emitting element LD may be connected to the first power voltage node VDDN through one or more transistors included in the sub-pixel circuit SPC.

The sub-pixel circuit SPC may be connected to an i-th gate line GLi among the first to m-th gate lines GL1 to GLm of FIG. 1, an i-th emission control line ELi among the first to m-th emission control lines EL1 to ELm of FIG. 1, and a j-th data line DLj among the first to n-th data lines DL1 to DLn of FIG. 1. The sub-pixel circuit SPC is configured to control the light emitting element LD in response to signals received through the aforementioned signal lines.

The sub-pixel circuit SPC may operate in response to a gate signal received through the i-th gate line GLi. The i-th gate line GLi may include one or more sub-gate lines. In one or more embodiments, as illustrated in FIG. 2, the i-th gate line GLi may include first and second sub-gate lines SGL1 and SGL2. The sub-pixel circuit SPC may operate in response to gate signals received through the first and second sub-gate lines SGL1 and SGL2. As such, in the case where the i-th gate line GLi includes two or more sub-gate lines, the sub-pixel circuit SPC may operate in response to gate signals received through the corresponding sub-gate lines.

The sub-pixel circuit SPC may operate in response to an emission control signal received through the i-th emission control line ELi. In one or more embodiments, the i-th emission control line ELi may include one or more sub-emission control lines. In the case where the i-th emission control line ELi includes two or more sub-emission control lines, the sub-pixel circuit SPC may operate in response to emission control signals received through the corresponding sub-emission control lines.

The sub-pixel circuit SPC may receive a data signal through a j-th data line DLj. The sub-pixel circuit SPC may store a voltage corresponding to the data signal in response to at least one of gate signals received through the first and second sub-gate lines SGL1 and SGL2. The sub-pixel circuit SPC may adjust current flowing from the first power voltage node VDDN to the second power voltage node VSSN through the light emitting element LD according to the stored voltage, in response to an emission control signal received through the i-th emission control line ELi. Therefore, the light emitting element LD may generate light with a luminance corresponding to the data signal.

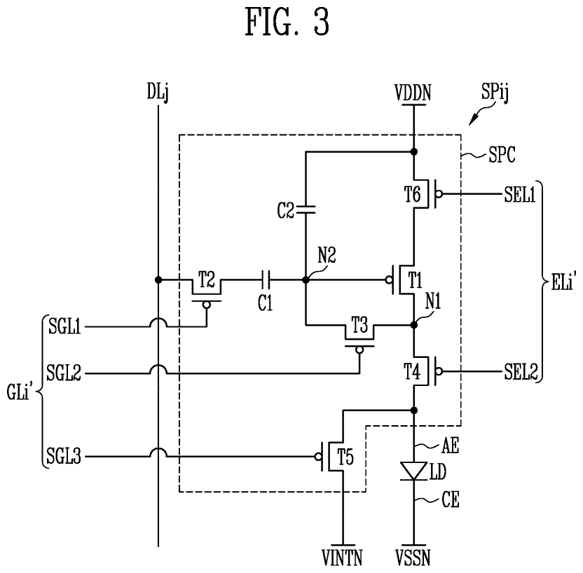

FIG. 3 is a circuit diagram illustrating one or more embodiments of the sub-pixel SPij of FIG. 2.

Referring to FIG. 3, the sub-pixel SPij may include a sub-pixel circuit SPC and a light emitting element LD.

The sub-pixel circuit SPC may be connected to an i-th gate line GLi′, an i-th emission control line ELi′, and a j-th data line DLj. Compared to the i-th gate line GLi of FIG. 2, the i-th gate line GLi′ may further include a third sub-gate line SGL3. Compared to the i-th emission control line ELi of FIG. 2, the i-emission control line ELi′ may include a first sub-emission control line SEL1 and a second sub-emission control line SEL2.

The sub-pixel circuit SPC may include first to sixth transistors T1 to T6, and first and second capacitors C1 and C2.

The first transistor T1 is connected between the first power voltage node VDDN and the first node N1. A gate of the first transistor T1 may be connected to a second node N2. Hence, the first transistor T1 may be turned on depending on the voltage level of the second node N2. The first transistor T1 may be referred to as a driving transistor.

The second transistor T2 may be connected between the j-th data line DLj and the second node N2. A gate of the second transistor T2 may be connected to a first sub-gate line SGL1. Hence, the second transistor T2 may be turned on in response to a gate signal of the first sub-gate line SGL1. The second transistor T2 may be referred to as a switching transistor.

The third transistors T3 may be connected between the first node N1 and the second node N2. A gate of the third transistor T3 may be connected to a second sub-gate line SGL2. Hence, the third transistor T3 may be turned on in response to a gate signal of the second sub-gate line SGL2.

The fourth transistor T4 may be connected between the first node N1 and the anode electrode AE of the light emitting element LD. A gate of the fourth transistor T4 may be connected to the second sub-emission control line SEL2. Hence, the fourth transistor T4 may be turned on in response to an emission control signal of the second sub-emission control line SEL2.

The fifth transistor T5 may be connected between the anode electrode AE of the light emitting element LD and an initialization voltage node VINTN. The initialization voltage node VINTN is configured to transmit an initialization voltage. In one or more embodiments, the initialization voltage may be provided by the voltage generator 140 of FIG. 1. In one or more embodiments, the initialization voltage may be provided by an external device of the display device 100. A gate of the fifth transistor T5 may be connected to the third sub-gate line SGL3. Hence, the fifth transistor T5 may be turned on in response to a gate signal of the third sub-gate line SGL3.

The sixth transistor T6 is connected between the first power voltage node VDDN and the first transistor T1. A gate of the sixth transistor T6 may be connected to the first sub-emission control line SEL1. Hence, the sixth transistor T6 may be turned on in response to an emission control signal of the first sub-emission control line SEL1.

The first capacitor C1 is connected between the second transistor T2 and the second node N2. The second capacitor C2 is connected between the first power voltage node VDDN and the second node N2.

As such, the sub-pixel circuit SPC may include the first to sixth transistors T1 to T6 and the first and second capacitors C1 and C2. However, one or more embodiments are not limited to the aforementioned example. The sub-pixel circuit SPC may be implemented as any one of one or more suitable forms of circuits each including a plurality of transistors and one or more capacitors. For example, the sub-pixel circuit SPC may include two transistors and one capacitor. Depending on embodiments of the sub-pixel circuit SPC, the number of sub-gate lines included in the i-th gate line GLi′ and the number of sub-emission control lines included in the i-th emission control line ELi′ may vary.

The first to sixth transistors T1 to T6 may include (e.g., be formed of) P-type (kind) transistors. Each of the first to sixth transistors T1 to T6 may include (e.g., be formed of) a metal oxide semiconductor field effect transistor (MOSFET). However, one or more embodiments are not limited to the aforementioned example. For example, at least one of the first to sixth transistors T1 to T6 may be replaced with to an N-type (kind) transistor.

In one or more embodiments, the first to sixth transistors T1 to T6 may include an amorphous silicon semiconductor, a monocrystalline silicon semiconductor, a polycrystalline silicon semiconductor, an oxide semiconductor, and/or the like.

The light emitting element LD may include the anode electrode AE, the cathode electrode CE, and an emission layer. The emission layer may be arranged between the anode electrode AE and the cathode electrode CE. If (e.g., when) emission control signals of the first and second sub-emission control lines SEL1 and SEL2 are enabled to a low level after a data signal transmitted through the j-th data line DLj is reflected in the voltage of the second node N2, the fourth and sixth transistors T4 and T6 may be turned on. Furthermore, the first transistor T1 may be turned on in response to the voltage of the second node N2, so that current may flow from the first power voltage node VDDN to the second power voltage node VSSN. The light emitting element LD may be configured to emit light corresponding to the amount of current.

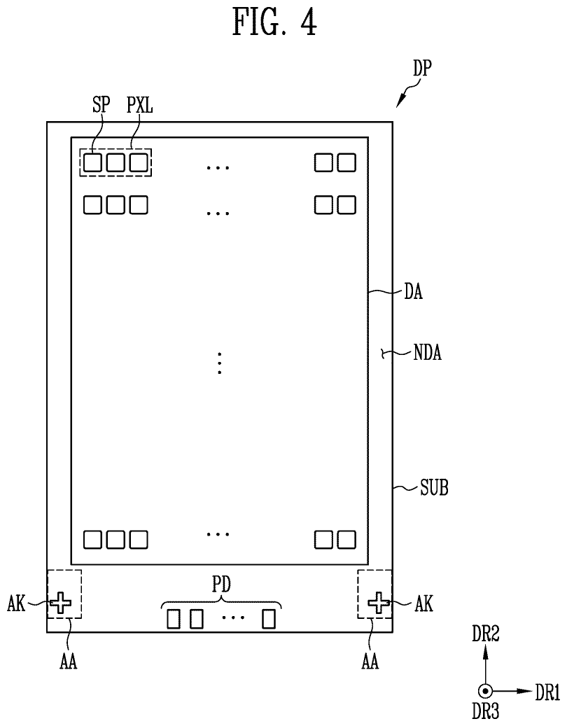

FIG. 4 is a plan view illustrating one or more embodiments of the display panel 110 of FIG. 1.

Referring to FIG. 4, a display panel DP corresponding to one or more embodiments of the display panel 110 depicted in FIG. 1 may include a display area DA and a non-display area NDA. The display panel DP may display an image through the display area DA. The non-display area NDA may enclose the display area DA. For example, the display area DA is inside the non-display area NDA.

The display panel DP may include a substrate SUB, sub-pixels SP, and pads PD.

The display panel DP is utilized as a display screen for a head-mounted display (HMD), a virtual reality (VR) device, a mixed reality (MR) device, an augmented reality (AR) device, and/or the like. In some embodiments, the display panel DP may be positioned extremely close to the eyes of the user. In this case, relatively high-density sub-pixels SP may be desired or required. To increase the pixel density of the sub-pixels SP, the substrate SUB may be provided utilizing a silicon substrate. The sub-pixels SP and/or the display panel DP may be formed on the substrate SUB that is a silicon substrate. The display device 100 (refer to FIG. 1) including the display panel DP formed on the substrate SUB that is a silicon substrate may be referred to as an OLED on Silicon (OLEDoS) display device.

The sub-pixels SP may be at (e.g., arranged in) the display area DA on the substrate SUB. The sub-pixels SP may be arranged in the form of a matrix along a first direction DR1 and a second direction DR2 crossing (e.g., intersecting with) the first direction DR1. However, one or more embodiments are not limited to the aforementioned example. For example, the sub-pixels SP may be arranged in a zigzag pattern in the first direction DR1 and the second direction DR2. For example, the sub-pixels SP may be arranged in a Pentile form (e.g., a PENTILE® arrangement structure (e.g., an RGBG matrix, RGBG structure, or RGBG matrix structure), but the present disclosure is not limited thereto. PENTILE® is a duly registered trademark of Samsung Display Co., Ltd. The first direction DR1 may refer to a row direction, and the second direction DR2 may refer to a column direction.

Two or more sub-pixels SP among (e.g., selected from among) the sub-pixels SP may form a pixel PXL. For example, three sub-pixels SP may form one pixel PXL.

Components for controlling the sub-pixels SP may be at (e.g., arranged in) the non-display area NDA on the substrate SUB. For example, connected to the sub-pixels SP, lines such as the first to m-th gate lines GL1 to GLm and the first to n-th data lines DL1 to DLn of FIG. 1 may be arranged in the non-display area NDA.

At least one of the gate driver 120, the data driver 130, the voltage generator 140, the controller 150, and the temperature sensor 160 of FIG. 1 may be integrated in the non-display area NDA of the display panel DP. In one or more embodiments, the gate driver 120 of FIG. 1 may be on (e.g., mounted on) the display panel DP and positioned in the non-display area NDA. In one or more embodiments, the gate driver 120 may be implemented as an integrated circuit separate from the display panel DP. In one or more embodiments, the temperature sensor 160 may be positioned in the non-display area NDA to sense the temperature of the display panel DP.

The pads PD may be at (e.g., arranged in) the non-display area NDA on the substrate SUB. The pads PD may be electrically connected to the sub-pixels SP through the lines. For example, the pads PD may be connected to the sub-pixels SP through the first to n-th data lines DL1 to DLn.

The pads PD may interface the display panel DP with other components of the display device 100 (refer to FIG. 1). In one or more embodiments, voltages and signals desired or required for the operation of the components included in the display panel DP may be provided through the pads PD from the driver integrated circuit DIC of FIG. 1. For example, the first to n-th data lines DL1 to DLn may be connected to the driver integrated circuit DIC through the pads PD. For example, the first and second power voltages VDD and VSS may be received from the driver integrated circuit DIC through the pads PD. For example, in the case where the gate driver 120 is mounted on the display panel DP, the gate control signal GCS may be transmitted from the driver integrated circuit DIC to the gate driver 120 through the pads PD.

In one or more embodiments, a circuit board may be electrically connected to the pads PD by a conductive adhesive component such as an anisotropic conductive film. Here, the circuit board may be a flexible circuit board (FPCB) and/or flexible film that includes (e.g., is made of) flexible materials. The driver integrated circuit DIC may be mounted on the circuit board and be electrically connected to the pads PD.

The non-display area NDA may include alignment areas AA. Each of the alignment areas AA may be adjacent to the display area DA and the pads PD. Alignment keys AK may be respectively arranged in the alignment areas AA on the substrate SUB. Each of the alignment keys AK may be at (e.g., arranged in) a portion of the corresponding alignment area AA. The alignment keys AK may be arranged symmetrically with respect to a center line of the display panel DP extending in the second direction DR2. The alignment keys AK function to enable alignment of equipment or components of the display panel DP during a process of manufacturing the components. For example, because the equipment recognizes the alignment keys AK and sets the position based on the alignment keys AK, the reliability of the process of manufacturing the display panel DP may be improved due to the alignment keys AK.

In one or more embodiments, the display area DA may have one or more suitable shapes. The display area DA may have a closed-loop shape, including linear and/or curved sides. For example, the display area DA may have shapes such as a polygon, a circle, a semicircle, and/or an ellipse.

In one or more embodiments, the display panel DP may have a planar display surface. In one or more embodiments, the display panel DP may have a display surface that is at least partially rounded. In one or more embodiments, the display panel DP may be bendable, foldable, and/or rollable. In the aforementioned cases, the display panel DP and/or the substrate SUB may include materials having flexible properties.

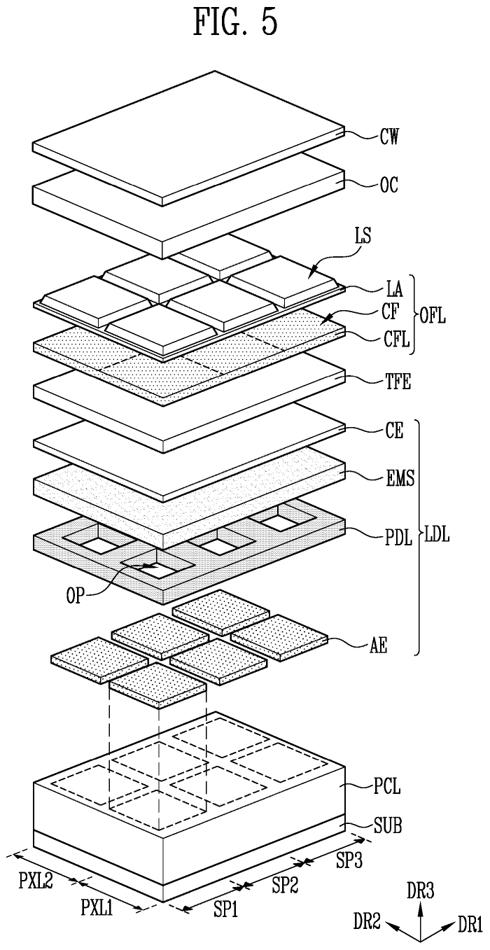

FIG. 5 is an exploded perspective view illustrating a portion of the display area DA of the display panel DP of FIG. 4. In FIG. 5, for the sake of clear and concise explanation, there is schematically illustrated a portion of the display panel DP corresponding to two pixels PXL1 and PXL2 among the pixels PXL of FIG. 4. The remaining portions of the display panel DP corresponding to the other pixels PXL may also be configured in substantially the same manner.

Referring to FIGS. 4 and 5, each of the first and second pixels PXL1 and PXL2 may include first to third sub-pixels SP1, SP2, and SP3. However, one or more embodiments are not limited to the aforementioned example. For example, each of the first and second pixels PXL1 and PXL2 may include four sub-pixels SP, or may include two sub-pixels SP.

In FIG. 5, the first to third sub-pixels SP1, SP2, and SP3 may have rectangular shapes and substantially the same size if (e.g., when) viewed in a third direction DR3 crossing (e.g., intersecting with) the first and second directions DR1 and DR2. However, one or more embodiments are not limited to the aforementioned example. The first to third sub-pixels SP1, SP2, and SP3 may be modified to have one or more suitable shapes.

The display panel DP may include a substrate SUB, a pixel circuit layer PCL, a light-emitting-element layer LDL, an encapsulation layer TFE, an optical functional layer OFL, an overcoat layer OC, and a cover window CW.

In one or more embodiments, the substrate SUB may include a silicon wafer substrate formed through a semiconductor process. The substrate SUB may include semiconductor material suitable for forming circuit elements. For example, the semiconductor material may include silicon, germanium, and/or silicon-germanium. The substrate SUB may be provided from a bulk wafer, an epitaxial layer, a silicon on insulator (SOI) layer, a semiconductor on insulator (SeOI) layer, and/or the like. In one or more embodiments, the substrate SUB may include a glass substrate. In one or more embodiments, the substrate SUB may include a polyimide (PI) substrate.

The pixel circuit layer PCL may be on (e.g., disposed/arranged on) the substrate SUB. The substrate SUB and/or the pixel circuit layer PCL may include insulating layers, and conductive patterns arranged between the insulating layers. The conductive patterns of the pixel circuit layer PCL may function as at least portions of the circuit components, lines, and/or the like. The conductive patterns may include copper, but one or more embodiments are not limited thereto.

The circuit elements may include respective sub-pixel circuits SPC (refer to FIG. 2) of the first to third sub-pixels SP1, SP2, and SP3. The sub-pixel circuit SPC may include transistors and one or more capacitors. Each transistor may include a semiconductor portion including a source area, a drain area, and a channel area, and a gate electrode overlapping the semiconductor portion. In one or more embodiments, in the case where the substrate SUB includes (e.g., is formed of) a silicon substrate, the semiconductor portion may be included in the substrate SUB, and the gate electrode may be included in the pixel circuit layer PCL as a conductive pattern of the pixel circuit layer PCL. In one or more embodiments, in the case where the substrate SUB includes a glass substrate or a PI substrate, the semiconductor portion and the gate electrode may be included in the pixel circuit layer PCL. Each capacitor may include electrodes spaced and/or apart (e.g., spaced apart or separated) from each other. For example, each capacitor may include electrodes spaced and/or apart (e.g., spaced apart or separated) from each other on a plane defined in the first and second directions DR1 and DR2. For example, each capacitor may include electrodes spaced and/or apart (e.g., spaced apart or separated) from each other in the third direction DR3 with an insulating layer therebetween (e.g., an insulating layer is interposed between every two electrodes.)

The lines of the pixel circuit layer PCL may include signal lines connected to each of the first to third sub-pixels SP1, SP2, and SP3, for example, a gate line, an emission control line, and a data line. The lines may further include a line connected to the first power voltage node VDDN of FIG. 2. Furthermore, the lines may further include a line connected to the second power voltage node VSSN of FIG. 2.

The light-emitting-element layer LDL may include anode electrodes AE, a pixel defining layer PDL, an emission structure EMS, and a cathode electrode CE.

The anode electrodes AE may be on (e.g., disposed/arranged on) the pixel circuit layer PCL. The anode electrodes AE may contact circuit elements of the pixel circuit layer PCL. The anode electrodes AE may include opaque conductive material capable of reflecting light, but one or more embodiments are not limited thereto.

The pixel defining layer PDL may be arranged on the anode electrodes AE. The pixel defining layer PDL may include openings OP that expose respective portions of the anode electrodes AE. Respective emission areas corresponding to the first to third sub-pixels SP1 to SP3 may be defined according to the openings OP in the pixel defining layer PDL. In one or more embodiments, the respective emission areas corresponding to the first to third sub-pixels SP1 to SP3 may be understood as being defined according to the anode electrodes AE. In an area adjacent to a boundary of neighboring sub-pixels, the pixel defining layer PDL may include a separator that causes a discontinuity to be formed at the emission structure EMS. In this case, the respective emission areas corresponding to the first to third sub-pixels SP1 to SP3 may be understood as being defined by the separators of the pixel defining layer PDL.

In one or more embodiments, the pixel defining layer PDL may include inorganic material. In this case, the pixel defining layer PDL may include a plurality of inorganic layers stacked on top of one another. For example, the pixel defining layer PDL may include silicon oxide (SiOₓ) and/or silicon nitride (SiNₓ). In one or more embodiments, the pixel defining layer PDL may include organic material. However, the material of the pixel defining layer PDL is not limited to the aforementioned examples.

The emission structure EMS may be on (e.g., arranged on) the anode electrodes AE exposed through the openings OP in the pixel defining layer PDL. The emission structure EMS may include an emission layer configured to generate light, an electron transport layer configured to transport electrons, and a hole transport layer configured to transport holes.

In one or more embodiments, the emission structure EMS may fill the openings OP in the pixel defining layer PDL and be arranged on an overall surface of an upper portion of the pixel defining layer PDL. For example, the emission structure EMS may extend over the first to third sub-pixels SP1 to SP3. In this case, at least some of the layers in the emission structure EMS may be interrupted or bent at boundaries between the first to third sub-pixels SP1 to SP3. However, one or more embodiments are not limited to the aforementioned example. For instance, portions of the emission structure EMS corresponding to the first to third sub-pixels SP1 to SP3 may be separated from each other, and each (e.g., each portion of the portions of the emission structure EMS) may be arranged in the corresponding opening OP in the pixel defining layer PDL.

The cathode electrode CE may be on (e.g., disposed/arranged on) the emission structure EMS. The cathode electrode CE may extend across the first to third sub-pixels SP1 to SP3. As such, the cathode electrode CE may be provided as a common electrode for the first to third sub-pixels SP1 to SP3.

The cathode electrode CE may be a thin-film metal layer having a thickness allowing light emitted from the emission structure EMS to pass therethrough. The cathode electrode CE may include (e.g., be made of) a metal material having a relatively small thickness, and/or a transparent conductive material. In one or more embodiments, the cathode electrode CE may include at least one of one or more suitable transparent conductive materials including indium tin oxide, indium zinc oxide, indium tin zinc oxide, aluminum zinc oxide, gallium zinc oxide, zinc tin oxide, and/or gallium tin oxide. In one or more embodiments, the cathode electrode CE may include at least one of silver (Ag), magnesium (Mg), and a compound or a mixture thereof. However, the material of the cathode electrode CE is not limited to the aforementioned examples.

An anode electrodes AE (e.g., any one of (e.g., selected from among) the anode electrodes AE), a portion of the emission structure EMS that overlap the anode electrode AE, and a portion of the cathode electrode CE that overlaps the portion of the emission structure EMS may be understood as constituting one light emitting element LD (refer to FIG. 2). For example, each of the light emitting elements of the first to third sub-pixels SP1 to SP3 may include one anode electrode AE, a portion of the emission structure EMS that overlaps the one anode electrode AE, and a portion of the cathode electrode CE that overlaps the portion of the emission structure EMS. In each of the first to third sub-pixels SP1 to SP3, holes injected from the anode electrode AE, and electrons injected from the cathode electrode CE are transported into the emission layer of the emission structure EMS, thus forming excitons. If (e.g., when) the excitons transition or relax from an excited state to a ground state, light may be generated. Depending on the amount of current flowing through the emission layer, the luminance of light may be determined. Depending on the configuration of the emission layer, the wavelength range of light to be generated may be determined. For example, the luminance of the light is determined by the amount of current (e.g., charge carriers (holes and electrons)) flowing through the emission layer, and the wavelength range of the light is determined by the configuration of the emission layer.

The encapsulation layer TFE may be on (e.g., arranged on) the cathode electrode CE. The encapsulation layer TFE may cover the light-emitting-element layer LDL and/or the pixel circuit layer PCL. The encapsulation layer TFE may be configured to prevent or reduce oxygen, water, and/or the like from penetrating into the light-emitting-element layer LDL. In one or more embodiments, the encapsulation layer TFE may include a structure formed by alternately stacking one or more inorganic layers and one or more organic layers. For example, the inorganic layer may include silicon nitride, silicon oxide, silicon oxynitride (SiOₓN_{y}), and/or the like. For example, the organic layer may include organic insulating material, such as acrylic resin, epoxy resin, phenol resin, polyamide resin, polyimide resin, unsaturated polyester resin, polyphenylenether resin, polyphenylenesulfide resin, and/or benzocyclobutene (BCB). However, the materials of the organic layer and the inorganic layer of the encapsulation layer TFE are not limited to the aforementioned examples.

The optical functional layer OFL may be on (e.g., disposed/arranged on the encapsulation layer TFE. The optical functional layer OFL may include a color filter layer CFL and a lens layer LA.

The color filter layer CFL may be arranged between the encapsulation layer TFE and the lens layer LA. The color filter layer CFL may be configured to filter light emitted from the emission structure EMS and selectively output light in a wavelength range and/or color corresponding to each sub-pixel SP. The color filter layer CFL may include color filters CF respectively corresponding to the first to third sub-pixels SP1 to SP3. Each of the color filters CF allows light within a wavelength range corresponding to the related sub-pixel SP to pass therethrough. For example, the color filter CF that corresponds to the first sub-pixel SP1 allows light in a red color to pass therethrough, the color filter CF that corresponds to the second sub-pixel SP2 allows light in a green color to pass therethrough, and the color filter CF that corresponds to the third sub-pixel SP3 allows light in a blue color to pass therethrough. Depending on the light emitted from the emission structure EMS of each sub-pixel SP, at least some of the color filters CF may not be provided.

The lens layer LA may be on (e.g., disposed/arranged on) the color filter layer CFL. The lens layer LA may include lenses LS that respectively correspond to the first to third sub-pixels SP1 to SP3. Each of the lenses LS may output and direct light emitted from the emission structure EMS along an intended path, thus enhancing the light output efficiency. The lens layer LA may have a relatively high refractive index. For example, the lens layer LA may have a higher refractive index than the overcoat layer OC. In one or more embodiments, the lenses LS may include organic material. In one or more embodiments, the lenses LS may include acrylic material. However, the material of the lenses LS is not limited to the aforementioned examples.

In one or more embodiments, compared to the opening OP of the pixel defining layer PDL, at least some of the color filters CF of the color filter layer CFL and at least some of the lenses LS of the lens layer LA may be shifted in a direction parallel to the plane defined in the first and second directions DR1 and DR2. For example, in a central area of the display area DA, the center of each color filter CF and the center of each lens LS may be aligned or overlapped with the center of the corresponding opening OP of the pixel defining layer PDL. For example, in the central area of the display area DA, the opening OP of the pixel defining layer PDL may completely overlap the corresponding color filter CF of the color filter layer CFL and the corresponding lens LS of the lens layer LA. In an area adjacent to the non-display area NDA within the display area DA, the center of the color filter CF and the center of the lens LS may be shifted in a planar direction from the center of the corresponding opening OP of the pixel defining layer PDL if (e.g., when) viewed in the third direction DR3. For example, in the area adjacent to the non-display area NDA within the display area DA, each opening OP of the pixel defining layer PDL may partially overlap the corresponding color filter CF of the color filter layer CFL and the corresponding lens LS of the lens layer LA. Accordingly, light emitted from the emission structure EMS in the central area of the display area DA may be efficiently outputted in the normal direction of the display surface. Light emitted from the emission structure EMS around the perimeter of the display area DA may be efficiently outputted in a direction inclined at a certain angle with respect to the normal direction of the display surface. For example, in one or more embodiments, compared to the openings OP of the pixel defining layer PDL, at least some of the color filters CF of the color filter layer CFL and at least some of the lenses LS of the lens layer LA may be shifted in a direction parallel to the plane defined by the first and second directions DR1 and DR2. Specifically, in the central area of the display area DA, the center of each color filter CF and the center of each lens LS may be aligned with the center of the corresponding opening OP of the pixel defining layer PDL, resulting in complete overlap. However, in areas adjacent to the non-display area NDA within the display area DA, the centers of the color filters CF and lenses LS may be shifted in a planar direction from the centers of the corresponding openings OP of the pixel defining layer PDL, leading to partial overlap when viewed in the third direction DR3, which is the vertical direction. Accordingly, light emitted from the emission structure EMS in the central area of the display area DA may be efficiently outputted in the normal direction of the display surface. In contrast, light emitted from the emission structure EMS around the perimeter of the display area DA may be efficiently outputted in a direction inclined at a certain angle with respect to the normal direction of the display surface.

The overcoat layer OC may be arranged on the lens layer LA. The overcoat layer OC may cover the optical functional layer OFL, the encapsulation layer TFE, the emission structure EMS, and/or the pixel circuit layer PCL. The overcoat layer OC may include one or more suitable materials for protecting underlying layers from foreign substances such as dust, water, and/or the like. For example, the overcoat layer OC may include at least one of an inorganic insulating layer and an organic insulating layer. For instance, the overcoat layer OC may include epoxy, but one or more embodiments are not limited thereto. The overcoat layer OC may have a lower refractive index than the lens layer LA.

The cover window CW may be on (e.g., disposed/arranged on) the overcoat layer OC. The cover window CW may be configured to protect underlying layers. The cover window CW may have a higher refractive index than the overcoat layer OC. The cover window CW may include glass, but one or more embodiments are not limited thereto. For example, the cover window CW may be an encapsulation glass layer configured to protect components arranged thereunder. In one or more embodiments, the cover window CW may not be provided.

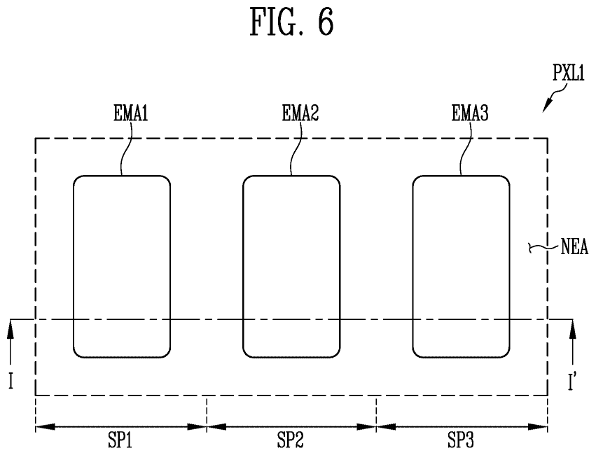

FIG. 6 is a plan view illustrating one or more embodiments of a first pixel of FIG. 5. In FIG. 6, for the sake of clear and concise explanation, the first pixel PXL1 of the first and second pixels PXL1 and PXL2 of FIG. 5 is schematically depicted. The other pixels PXL may be configured in substantially the same manner as the first pixel PXL1.

Referring to FIGS. 5 and 6, the first pixel PXL1 may include first to third sub-pixels SP1 to SP3 arranged in the first direction DR1.

The first sub-pixel SP1 may include a first emission area EMA1 and a non-emission area NEA formed around the first emission area EMA1. The second sub-pixel SP2 may include a second emission area EMA2 and a non-emission area NEA formed around the second emission area EMA2. The third sub-pixel SP3 may include a third emission area EMA3 and a non-emission area NEA formed around the third emission area EMA3.

The first emission area EMA1 may be an area where light is emitted from a portion of the emission structure EMS (refer to FIG. 5) that corresponds to the first sub-pixel SP1. The second emission area EMA2 may be an area where light is emitted from a portion of the emission structure EMS that corresponds to the second sub-pixel SP2. The third emission area EMA3 may be an area where light is emitted from a portion of the emission structure EMS that corresponds to the third sub-pixel SP3.

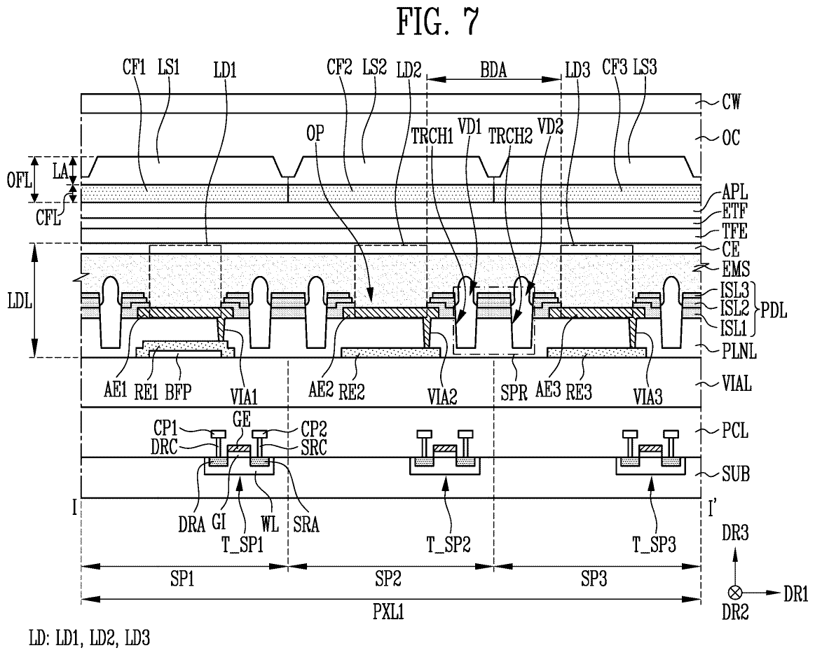

FIG. 7 is a sectional view taken along the line I-I′ of FIG. 6 in accordance with one or more embodiments of the present disclosure.

Referring to FIG. 7, there are provided the substrate SUB and the pixel circuit layer PCL arranged on the substrate SUB.

The substrate SUB may include a silicon wafer substrate formed through a semiconductor process. For example, the substrate SUB may include silicon, germanium, and/or silicon-germanium.

The pixel circuit layer PCL may be on (e.g., disposed/arranged on the substrate SUB. The substrate SUB and the pixel circuit layer PCL may include respective circuit elements of the first to third sub-pixels SP1 to SP3. For example, the substrate SUB and the pixel circuit layer PCL may include a transistor T_SP1 of the first sub-pixel SP1, a transistor T_SP2 of the second sub-pixel SP2, and a transistor T_SP3 of the third sub-pixel SP3. The transistor T_SP1 of the first sub-pixel SP1 may be any one of the transistors included in the sub-pixel circuit SPC (refer to FIG. 2) of the first sub-pixel SP1. The transistor T_SP2 of the second sub-pixel SP2 may be any one of the transistors included in the sub-pixel circuit SPC of the second sub-pixel SP2. The transistor T_SP3 of the third sub-pixel SP3 may be any one of the transistors included in the sub-pixel circuit SPC of the third sub-pixel SP3. In FIG. 7, one of the transistors of each sub-pixel is illustrated for the sake of clear and concise explanation, and the remaining circuit elements are not provided.

The transistor T_SP1 of the first sub-pixel SP1 may include a source area SRA, a drain area DRA, and a gate electrode GE.

The source area SRA and the drain area DRA may be arranged in the substrate SUB. Formed through an ion injection process, a well WL may be formed at (e.g., arranged in) the substrate SUB. The source area SRA and the drain area DRA may be arranged to be spaced and/or apart (e.g., spaced apart or separated) from each other in the well WL. An area between the source area SRA and the drain area DRA in the well WL may be defined as a channel area. The gate electrode GE may overlap the channel area between the source area SRA and the drain area DRA, and may be at (e.g., arranged in) the pixel circuit layer PCL. The gate electrode GE may be spaced and/or apart (e.g., spaced apart or separated) from the well WL or the channel area by an insulating layer such as a gate insulating layer GI. The gate electrode GE may include conductive material.

A plurality of layers of the pixel circuit layer PCL (e.g., the plurality of layers included in the pixel circuit layer PCL) may include insulating layers and conductive patterns arranged between the insulating layers. The conductive patterns may include first and second conductive patterns CP1 and CP2. The first conductive pattern CP1 may be electrically connected to the drain area DRA through a drain connector DRC passing through one or more insulating layers. The second conductive pattern CP2 may be electrically connected to the source area SRA through a source connector SRC passing through one or more insulating layers.

As the gate electrode GE and the first and second conductive patterns CP1 and CP2 are connected to other circuit elements and/or lines, the transistor T_SP1 of the first sub-pixel SP1 may be provided as one of the transistors of the first sub-pixel SP1.

Each of the transistor T_SP2 of the second sub-pixel SP2 and the transistor T_SP3 of the third sub-pixel SP3 may be configured in substantially the same manner as the transistor T_SP1 of the first sub-pixel SP1.

As such, the substrate SUB and the pixel circuit layer PCL may include respective circuit elements of the first to third sub-pixels SP1 to SP3.

A via layer VIAL may be on (e.g., disposed/arranged on) the pixel circuit layer PCL. The via layer VIAL may cover the pixel circuit layer PCL, and have an overall even surface. The via layer VIAL is configured to planarize stepped portions on the pixel circuit layer PCL. The via layer VIAL may include at least one of silicon oxide (SiOₓ), silicon nitride (SiNₓ), and silicon carbon nitride (SiCN), but one or more embodiments are not limited thereto.

The light-emitting-element layer LDL may be on (e.g., arranged on) the via layer VIAL. The light-emitting-element layer LDL may include first to third reflective electrodes RE1 to RE3, a planarization layer PLNL, first to third anode electrodes AE1 to AE3, a pixel defining layer PDL, an emission structure EMS, and a cathode electrode CE.

The first to third reflective electrodes RE1 to RE3 may be respectively formed at (e.g., disposed/arranged in) the first to third sub-pixels SP1 to SP3 on the via layer VIAL. Each of the first to third reflective electrodes RE1 to RE3 may contact a circuit element arranged in the pixel circuit layer PCL through a corresponding via passing through the via layer VIAL.

The first to third reflective electrodes RE1 to RE3 may function as full mirrors provided to reflect light emitted from the emission structure EMS toward the display surface (or the cover window CW). The first to third reflective electrodes RE1 to RE3 may include metallic materials suitable for reflecting light. The first to third reflective electrodes RE1 to RE3 may include at least one of aluminum (Al), silver (Ag), magnesium (Mg), platinum (Pt), palladium (Pd), gold (Au), nickel (Ni), neodymium (Nd), iridium (Ir), chromium (Cr), titanium (Ti), and/or an alloy of two or more materials selected from among the aforementioned materials, but one or more embodiments are not limited thereto.

In one or more embodiments, a connection electrode may be arranged under each of the first to third reflective electrodes RE1 to RE3. The connection electrode may enhance electrical connection characteristics between the corresponding reflective electrode and the corresponding circuit element of the pixel circuit layer PCL. The connection electrode may have a multilayer structure. The multilayer structure may include titanium (Ti), titanium nitride (TiN), tantalum nitride (TaN), and/or the like, but one or more embodiments are not limited thereto. In one or more embodiments, a corresponding reflective electrode may be positioned between multiple layers of the connection electrode.

A buffer pattern BFP may be arranged under at least one of the first to third reflective electrodes RE1 to RE3 (e.g., at least one of the first reflective electrode RE1, the second reflective electrode RE2 and the third reflective electrode RE3). The buffer pattern BFP may include inorganic material such as silicon carbon nitride, but one or more embodiments are not limited thereto. As the buffer pattern BFP is arranged, the height of the corresponding reflective electrode in the third direction DR3 may be adjusted. For example, the buffer pattern BFP may be arranged between the first reflective electrode RE1 and the via layer VIAL, thus adjusting the height of the first reflective electrode RE1.

The first to third reflective electrodes RE1 to RE3 may function as full mirrors, and the cathode electrode CE may function as a half mirror. For example, each of the first to third reflective electrodes RE1 to RE3 and the cathode electrode CE may provide a resonant structure in the corresponding sub-pixel. Light emitted from the emission layer of the emission structure EMS may be amplified by reciprocating between the corresponding reflective electrode and the cathode electrode CE. The amplified light may be output through the cathode electrode CE. In this way, the distance between each reflective electrode and the cathode electrode CE may be understood as a resonant distance for the light emitted from the emission layer of the corresponding emission structure EMS.

The first sub-pixel SP1 may have a resonant distance shorter than other sub-pixels due to the buffer pattern BFP. As such, the adjusted resonant distance makes it possible for light in a specific wavelength range (e.g., red color) to be efficiently amplified. Consequently, the first sub-pixel SP1 may effectively and efficiently output light in the corresponding wavelength range.

In FIG. 7, the buffer pattern BFP is provided in the first sub-pixel SP1 but is not provided in the second and third sub-pixels SP2 and SP3, but one or more embodiments are not limited thereto. The buffer pattern BFP may also be provided in at least one of the second sub-pixel SP2 and the third sub-pixel SP3, so that the resonant distance of at least one of the second sub-pixel SP2 and the third sub-pixel SP3 may be adjusted. For example, the first to third sub-pixels SP1 to SP3 may respectively correspond to red, green, and blue. The distance between the first reflective electrode RE1 and the cathode electrode CE may be less than the distance between the second reflective electrode RE2 and the cathode electrode CE. The distance between the second reflective electrode RE2 and the cathode electrode CE may be less than the distance between the third reflective electrode RE3 and the cathode electrode CE.

To planarize the stepped portions (e.g., height differences or steps between different layers) between the first to third reflective electrodes RE1 to RE3, the planarization layer PLNL may be arranged on the via layer VIAL and the first to third reflective electrodes RE1 to RE3. The planarization layer PLNL may cover overall surfaces of the first to third reflective electrodes RE1 to RE3 and the via layer VIAL, and have an even surface. In one or more embodiments, the planarization layer PLNL may not be provided.

On the planarization layer PLNL, the first to third anode electrodes AE1 to AE3 may be arranged, overlapping the first to third reflective electrodes RE1 to RE3, respectively. The first to third anode electrodes AE1 to AE3 may have shapes similar to the first to third emission areas EMA1 to EMA3 of FIG. 6 if (e.g., when) viewed in the third direction DR3. The first to third anode electrodes AE1 to AE3 are respectively connected to the first to third reflective electrodes RE1 to RE3. The first anode electrode AE1 may be connected to the first reflective electrode RE1 through a first via VIA1 passing through the planarization layer PLNL. The second anode electrode AE2 may be connected to the second reflective electrode RE2 through a second via VIA2 passing through the planarization layer PLNL. The third anode electrode AE3 may be connected to the third reflective electrode RE3 through a third via VIA3 passing through the planarization layer PLNL.

In one or more embodiments, the first to third anode electrodes AE1 to AE3 may include at least one of transparent conductive materials, such as indium tin oxide (ITO), indium zinc oxide (IZO), zinc oxide (ZnOₓ), indium gallium zinc oxide (IGZO), and/or indium tin zinc oxide (ITZO). However, the material of the first to third anode electrodes AE1 to AE3 is not limited to the aforementioned examples. For example, the first to third anode electrodes AE1 to AE3 may include titanium nitride.

The pixel defining layer PDL may be arranged on the planarization layer PLNL and portions of the first to third anode electrodes AE1 to AE3. The pixel defining layer PDL may include openings OP that expose respective portions of the first to third anode electrodes AE1 to AE3. An area overlapping the pixel defining layer PDL may be understood as a boundary area BDA between adjacent sub-pixels SP.

In one or more embodiments, the pixel defining layer PDL may include a plurality of inorganic insulating layers. Each of the inorganic insulating layers may include at least one of silicon oxide (SiOₓ) and silicon nitride (SiNₓ). For example, the pixel defining layer PDL may include a first inorganic insulating layer ISL1, a second inorganic insulating layer ISL2, and a third inorganic insulating layer ISL3 that are sequentially stacked. The first to third inorganic insulating layers ISL1 to ISL3 may include silicon nitride, silicon oxide, and/or silicon nitride, but one or more embodiments are not limited thereto. The first to third inorganic insulating layers ISL1 to ISL3 may have a stepped cross-section in an area adjacent to each of the openings OP.

The pixel defining layer PDL may include a separator SPR provided in the boundary area BDA between adjacent sub-pixels SP. For example, the separator SPR may be provided in each of the boundary areas BDA between the sub-pixels SP.

The separator SPR may result in creation of discontinuities in the emission structure EMS in the boundary area BDA. For example, the emission structure EMS may be interrupted or bent in the boundary area BDA by the separator SPR. Accordingly, the first to third emission areas EMA1 to EMA3 of FIG. 6 that respectively correspond to the first to third sub-pixels SP1 to SP3 may be defined along the separators SPR of the pixel defining layer PDL.

The separator SPR may be provided in or on the pixel defining layer PDL. The pixel defining layer PDL may include one or more trenches TRCH1 and TRCH2 in the boundary area BDA as the separator SPR. In one or more embodiments, as illustrated in FIG. 7, the one or more trenches TRCH1 and TRCH2 may pass through the pixel defining layer PDL and partially pass through the planarization layer PLNL. In one or more embodiments, the one or more trenches TRCH1 and TRCH2 may pass through the pixel defining layer PDL and the planarization layer PLNL and partially pass through the via layer VIAL. In one or more embodiments, the one or more trenches TRCH1 and TRCH2 may pass at least partially through the planarization layer PLNL and/or the via layer VIAL, and a portion of the pixel defining layer PDL may be at (e.g., arranged in) the one or more trenches TRCH1 and TRCH2.

In FIG. 7, the two trenches TRCH1 and TRCH2 are provided in the boundary area BDA. However, one or more embodiments are not limited to the aforementioned example. For example, the pixel defining layer PDL may include one trench in the boundary area BDA. In one or more embodiments, the pixel defining layer PDL may include three or more trenches in the boundary area BDA.

Due to the first and second trenches TRCH1 and TRCH2, discontinuities such as a first void VD1 and a second void VD2 in the boundary area BDA may be formed at (e.g., in) the emission structure EMS. Some of the plurality of layers stacked in the emission structure EMS may be interrupted or bent by the first and second voids VD1 and VD2. For example, at least one charge generation layer and at least one hole injection layer that are included in the emission structure EMS may be severed at the first and second voids VD1 and VD2. As such, due to the first and second trenches TRCH1 and TRCH2, portions of the emission structure EMS included in the first to third sub-pixels SP1 to SP3 are at least partially separated from each other. For example, as a result of the first and second trenches TRCH1 and TRCH2, the emission structure EMS within the first to third sub-pixels SP1 to SP3 is at least partially divided. This refers to that the layers of the emission structure EMS in these sub-pixels SP are not continuous and are separated by the voids VD1 and VD2 created by the trenches TRCH1 and TRCH2.

Depending on the shapes of the first and second trenches TRCH1 and TRCH2, the discontinuities formed at the emission structure EMS may be changed in one or more suitable ways.

In one or more embodiments, the emission structure EMS may be formed through a process such as vacuum deposition, and/or inkjet printing. In this case, the substantially same materials as the emission structure EMS may be positioned on bottom surfaces adjacent to the via layer VIAL in the first and second trenches TRCH1 and TRCH2.

The pixel defining layer PDL may include an additional separator to allow the emission structure EMS to further include a discontinuity adjacent to the boundary area BDA. In one or more embodiments, the third inorganic insulating layer ISL3, which is the uppermost layer among the first to third inorganic insulating layers ISL1 to ISL3 of the pixel defining layer PDL, may have a width greater than that of the second inorganic insulating layer ISL2 positioned directly thereunder. For example, the pixel defining layer PDL may have a “T”-shaped or “I” shaped cross-section in the boundary area BDA. Depending on the shape of the pixel defining layer PDL, a plurality of layers included in the emission structure EMS may be at least partially severed or bent in the boundary area BDA and/or an area adjacent to the boundary area BDA.

The emission structure EMS may be arranged on the anode electrodes AE exposed through the openings OP in the pixel defining layer PDL. The emission structure EMS may be charged into the openings OP of the pixel defining layer PDL, and be arranged across the overall areas of the first to third sub-pixels SP1 to SP3. As described above, the emission structure EMS may be at least partially severed or bent in the boundary area BDA by the separator SPR. Consequently, during the operation of the display panel DP, current leaking from each of the first to third sub-pixels SP1 to SP3 to the adjacent sub-pixel through the layers included in the emission structure EMS may be prevented or reduced. As a result, the first to third light emitting elements LD1 to LD3 may operate with relatively high reliability.

The cathode electrode CE may be arranged on the emission structure EMS. The cathode electrode CE may be provided in common in the first to third sub-pixels SP1 to SP3. The cathode electrode CE may function as a half mirror, partially transmitting and partially reflecting light emitted from the emission structure EMS.

The first anode electrode AE1, the portion of the emission structure EMS that overlaps the first anode electrode AE1, the portion of the cathode electrode CE that overlaps the first anode electrode AE1 may form a first light emitting element LD1. The second anode electrode AE2, the portion of the emission structure EMS that overlaps the second anode electrode AE2, and the portion of the cathode electrode CE that overlaps the second anode electrode AE2 may form a second light emitting element LD2. The third anode electrode AE3, the portion of the emission structure EMS that overlaps the third anode electrode AE3, and the portion of the cathode electrode CE that overlaps the third anode electrode AE3 may form a third light emitting element LD3.

The encapsulation layer TFE may be arranged on the cathode electrode CE. The encapsulation layer TFE may prevent or reduce oxygen, water, and/or the like from penetrating into the light-emitting-element layer LDL.

To enhance the encapsulation efficiency of the encapsulation layer TFE, an encapsulation thin-film ETF including aluminum oxide (Al₂O₃) may be further arranged on the encapsulation layer TFE. The encapsulation thin-film ETF including aluminum oxide may be positioned on an upper surface of the encapsulation layer TFE that faces the optical functional layer OFL and/or under a lower surface of the encapsulation layer TFE that faces the light-emitting-element layer LDL.

The encapsulation thin-film ETF including aluminum oxide may be formed through an atomic layer deposition (ALD) method. However, one or more embodiments are not limited to the aforementioned example. Thin films including at least one of one or more suitable materials suitable for enhancing the encapsulation efficiency may be further arranged over and under the encapsulation layer TFE.

The optical functional layer OFL may be arranged on the encapsulation thin-film ETF. In one or more embodiments, the optical functional layer OFL may be attached to the encapsulation thin-film ETF through an adhesive layer APL. For example, the optical functional layer OFL may be manufactured through a separate process and attached to the encapsulation layer TFE by the adhesive layer APL. The adhesive layer APL may further function to protect lower layers including the encapsulation thin-film ETF and upper layers including the color filter layer CFL. The adhesive layer APL may include acrylic resin.

The optical functional layer OFL may include a color filter layer CFL and a lens layer LA. The color filter layer CFL may include first to third color filters CF1 to CF3 respectively corresponding to the first to third sub-pixels SP1 to SP3. The first to third color filters CF1 to CF3 may be to transmit light in different wavelength ranges. For example, the first to third color filters CF1 to CF3 may respectively transmit red light, green light, and blue light.

In one or more embodiments, the first to third color filters CF1 to CF3 may partially overlap each other in the boundary area BDA. In one or more embodiments, the first to third color filters CF1 to CF3 may be spaced and/or apart (e.g., spaced apart or separated) from each other, and a black matrix may be provided between the first to third color filters CF1 to CF3.

The lens layer LA may be arranged on the color filter layer CFL. The lens layer LA may include first to third lenses LS1 to LS3 that respectively correspond to the first to third sub-pixels SP1 to SP3. The first to third lenses LS1 to LS3 may respectively direct light emitted from the first to third light emitting elements LD1 to LD3 in intended paths, thus enhancing the light output efficiency.

The overcoat layer OC may be arranged on the lens layer LA. The overcoat layer OC may be configured to protect underlying layers provided thereunder from foreign substances such as dust and/or water. The cover window CW may be arranged on the overcoat layer OC.

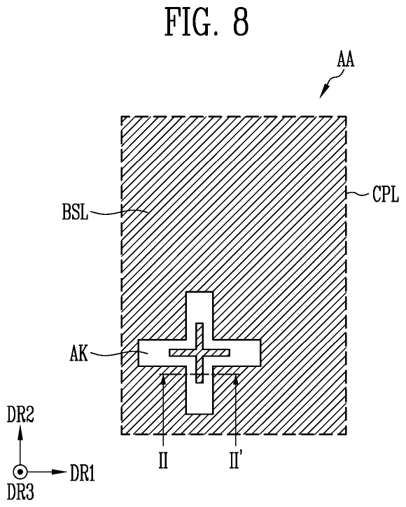

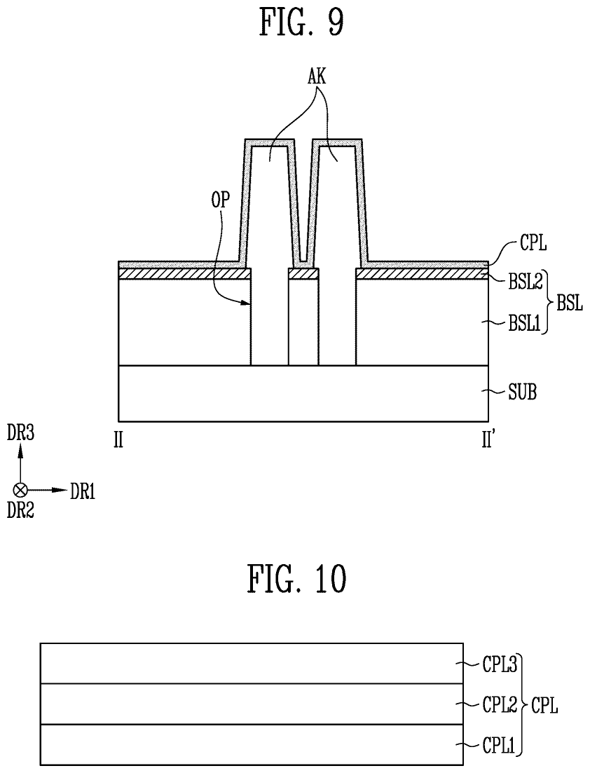

FIG. 8 is an enlarged plan view illustrating the alignment area AA of FIG. 4. FIG. 9 is a sectional view taken along the line II-II′ of FIG. 8.

Referring to FIGS. 8 and 9, the alignment key AK may be at (e.g., disposed/arranged in) a portion of the alignment area AA on the substrate SUB. The base layer BSL may be on (e.g., arranged on) the substrate SUB in the entirety of the alignment area AA other than the alignment key AK. For example, the base layer BSL may define an opening OP′ corresponding to the alignment key AK. The alignment key AK may be arranged at the opening OP′ of the base layer BSL. Accordingly, in a plan view, the base layer BSL may enclose the periphery of the alignment key AK.

The alignment key AK may have a shape protruding from an upper surface of the base layer BSL in the third direction DR3. For example, the alignment key AK may be formed in an embossed pattern. The alignment key AK may include inorganic material. The alignment key AK may have a multilayer structure formed by stacking inorganic layers including inorganic material. In more detail, the alignment key AK may include at least one of tetraethyl orthosilicate (TEOS), plasma enhanced oxide (PEOX) and silicon nitride.

The alignment key AK may have a cross shape in a plan view. However, in embodiments, the shape of the alignment key AK is not limited to the aforementioned example.

The base layer BSL may include a first base layer BSL1 and a second base layer BSL2. The first base layer BSL1 may be on (e.g., disposed/arranged on) the substrate SUB. One or more suitable layers including one or more conductive layers and/or insulating layers may be arranged between the first base layer BSL1 and the substrate SUB. The second base layer BSL2 may be on (e.g., arranged on) the first base layer BSL1. An opening corresponding to the alignment key AK in the first base layer BSL1 and an opening corresponding to the alignment key AK in the second base layer BSL2 may form the opening OP′ included in the base layer BSL.

A reflectance of the first base layer BSL1 may be higher than that of the second base layer BSL2. For example, the first base layer BSL1 may include aluminum, and the second base layer BSL2 may include titanium nitride. However, one or more embodiments are not limited thereto.

The capping layer CPL may be arranged on the alignment key AK and the base layer BSL. The capping layer CPL may cover the entirety of the alignment area AA, thereby covering both the alignment key AK and the base layer BSL (e.g., simultaneously).

The capping layer CPL may include inorganic material. The capping layer CPL may include material having high transmittance and low reflectance. The capping layer CPL may include at least one of aluminum oxide and acrylic resin. Accordingly, the capping layer CPL may mitigate the reflectance of the surface of the alignment key AK and the base layer BSL.

FIG. 10 is an enlarged sectional view illustrating the capping layer of FIG. 9.

Referring further to FIG. 10, the capping layer CPL may include first to third capping layers CPL1 to CPL3. The first capping layer CPL1 may be on (e.g., disposed/arranged on) the alignment key AK and the second base layer BSL2, and may include aluminum oxide. The second capping layer CPL2 may be on (e.g., disposed/arranged on) the first capping layer CPL1, and may include acrylic resin. The third capping layer CPL3 may be on (e.g., disposed/arranged on) the second capping layer CPL2, and may include acrylic resin. However, one or more embodiments are not limited to the aforementioned examples. In one or more embodiments, the capping layer CPL may include only the first capping layer CPL1. In one or more embodiments, the capping layer CPL may include only the first and second capping layers CPL1 and CPL2 including different materials.

Referring further to FIG. 7, the first capping layer CPL1 in the alignment area AA may include the same material as the encapsulation thin-film ETF in the display area DA. For example, the first capping layer CPL1 in the alignment area AA may be formed concurrently (e.g., simultaneously) with the encapsulation thin-film ETF in the display area DA. Furthermore, the second capping layer CPL2 in the alignment area AA may have the same material as the adhesive layer APL in the display area DA. For example, the second capping layer CPL2 in the alignment area AA may be formed concurrently (e.g., simultaneously) with the adhesive layer APL in the display area DA. Furthermore, the third capping layer CPL3 in the alignment area AA may have the same material as the lens layer LA in the display area DA. For example, the third capping layer CPL3 in the alignment area AA may be formed concurrently (e.g., simultaneously) with the lens layer LA in the display area DA.

In one or more embodiments, the capping layer CPL including inorganic material may be arranged on the alignment key AK and the base layer BSL across the entire alignment area AA, thereby protecting the base layer BSL. Therefore, the capping layer CPL may prevent or reduce the second base layer BSL2 from being lost during the manufacturing process. The alignment key AK is recognized through reflectance difference between the alignment key AK and the base layer BSL. The reflectance difference between the alignment key AK and the base layer BSL may be maintained through the capping layer CPL. Furthermore, the capping layer CPL may reduce the reflectance of the alignment area AA. As a result, the overall reflectance of the alignment area AA is reduced, thereby mitigating recognition failure where the alignment key AK is not recognized due to high reflectance of the first base layer BSL1. Therefore, as the recognition rate of the alignment key AK is enhanced, the reliability of the display device manufactured utilizing the alignment key AK may be improved.

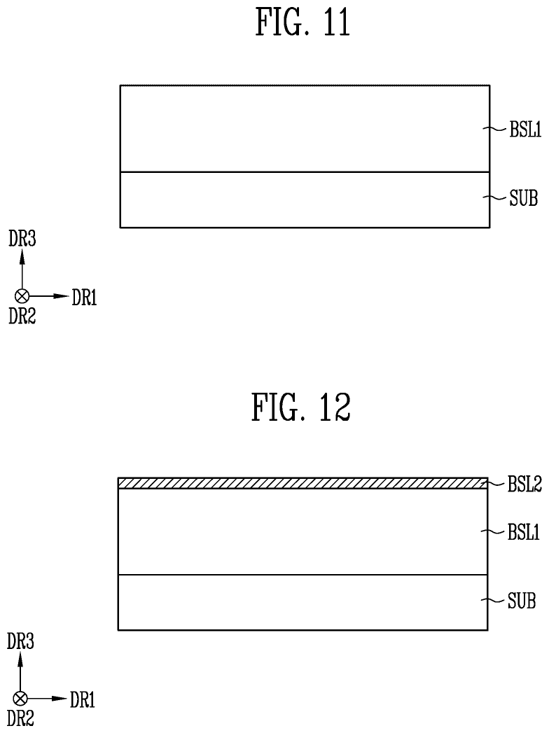

FIGS. 11 to 16 are diagrams illustrating operations (e.g., steps) of a method of manufacturing the display device in accordance with embodiments of the present disclosure.

Referring to FIG. 11, the first base layer BSL1 may be formed at the alignment area AA (refer to FIG. 8) included in the non-display area NDA (refer to FIG. 4) on the substrate SUB. For example, the first base layer BSL1 may include (e.g., be formed of) aluminum. One or more conductive layers and/or insulating layers may be formed between the substrate SUB and the first base layer BSL1.

Referring to FIG. 12, the second base layer BSL2 may be formed at the alignment area AA on the first base layer BSL1. The reflectance of the material forming the first base layer BSL1 may be higher than that of the material forming the second base layer BSL2. For example, the second base layer BSL2 may include (e.g., be formed of) titanium nitride.

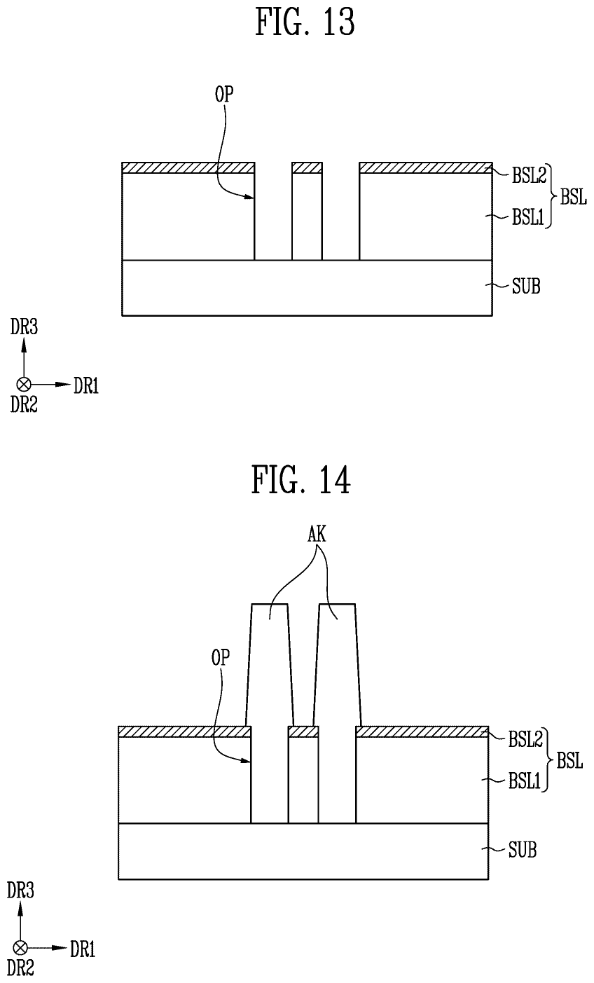

Referring to FIG. 13, the opening OP′ may be formed by patterning portions of the first base layer BSL1 and the second base layer BSL2. The opening OP′ may be formed at a portion of the alignment area AA. In one or more embodiments, a single opening OP′ may be formed concurrently (e.g., simultaneously) in the first base layer BSL1 and the second base layer BSL2. In one or more embodiments, a first opening may be formed at the first base layer BSL1, and a second opening overlapping the first opening of the first base layer BSL1 may be formed at the second base layer BSL2, thus forming a single large opening OP′. As a result, the base layer BSL may be formed, defining the opening OP′ and including the first base layer BSL1 and the second base layer BSL2.

Referring to FIG. 14, the alignment key AK may be formed at the opening OP′. Accordingly, the alignment key AK may be positioned in a portion of the alignment area AA, with the base layer BSL arranged around the alignment key AK. The alignment key AK may be formed to protrude from the upper surface of the base layer BSL. For example, the alignment key AK may be formed in an embossed pattern. Here, the alignment key AK may have a multilayer structure formed by stacking inorganic layers including inorganic material.

The alignment key AK may be formed in a cross shape in a plan view. However, in one or more embodiments, the shape of the alignment key AK is not limited to the aforementioned example.

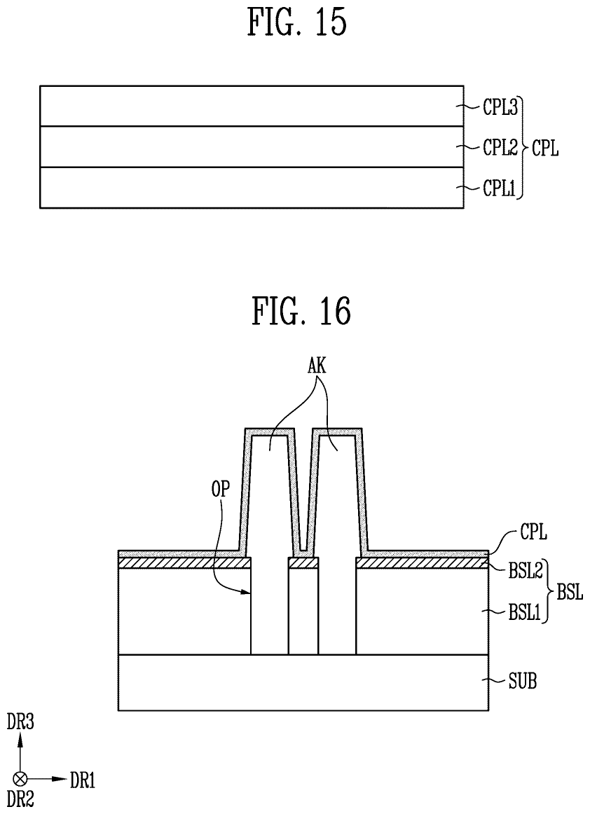

Referring to FIGS. 15 and 16, the capping layer CPL may be on (e.g., formed on) the alignment key AK and the base layer BSL in the entire alignment area AA. The capping layer CPL may include inorganic material. In one or more embodiments, the capping layer CPL may include the first to third capping layers CPL1 to CPL3 that are sequentially stacked and include different materials.

For example, in the alignment area AA, the first capping layer CPL1 may be formed on the alignment key AK and the base layer BSL. The first capping layer CPL1 may include (e.g., be formed of) aluminum oxide.

In the alignment area AA, the second capping layer CPL2 may be on (e.g., formed on) the first capping layer CPL1. The second capping layer CPL2 may include (e.g., be formed of) acrylic resin.

In the alignment area AA, the third capping layer CPL3 may be on (e.g., formed on) the second capping layer CPL2. The third capping layer CPL3 may include (e.g., be formed of) acrylic resin.

As a result, the capping layer CPL including the first to third capping layers CPL1 to CPL3 including different materials may be formed.

In one or more embodiments, only the first capping layer CPL1 may form the capping layer CPL. In one or more embodiments, the first capping layer CPL1 and the second capping layer CPL2 including different materials may form the capping layer CPL. For example, the capping layer CPL may include aluminum oxide, and may selectively include acrylic resin.

Referring further to FIG. 7, the light emitting elements LD may be formed at the display area DA on the substrate SUB. In the display area DA, the encapsulation layer TFE and the encapsulation thin-film ETF may be on (e.g., formed on) the light emitting elements LD. The encapsulation thin-film ETF may include (e.g., be formed of) aluminum oxide. The first capping layer CPL1 may include (e.g., be formed of) substantially the same material as the encapsulation thin-film ETF in the display area DA, and may be formed concurrently (e.g., simultaneously).

In the display area DA, the adhesive layer APL may be on (e.g., formed on) the encapsulation thin-film ETF. The adhesive layer APL may include (e.g., be formed of) acrylic resin. The second capping layer CPL2 may include (e.g., be formed of) substantially the same material as the adhesive layer APL in the display area DA, and may be formed concurrently (e.g., simultaneously).

In the display area DA, the color filter layer CFL may be on (e.g., formed on) the adhesive layer APL. In the display area DA, the lens layer LA may be on (e.g., formed on) the color filter layer CFL. The lens layer LA may be formed in a lens shape by forming an acrylic resin layer in the entire display area DA and then patterning the acrylic resin layer. The third capping layer CPL3 may include (e.g., be formed of) substantially the same material as the lens layer LA in the display area DA, and may be formed concurrently (e.g., simultaneously). However, unlike the lens layer LA, a patterning process may not be performed for the third capping layer CPL3.

In one or more embodiments, as the capping layer CPL including inorganic material is arranged on the alignment key AK and the base layer BSL over the entire the alignment area AA, the capping layer CPL may protect the base layer BSL, thus preventing or reducing the base layer BSL from being etched during the manufacturing process. Accordingly, due to the capping layer CPL, the reflectance of the alignment area AA where the alignment key AK and the base layer BSL are arranged may be reduced. As a result, failure in recognition of the alignment key AK attributable to high reflectance during the manufacturing process may be reduced, thereby enhancing the reliability of the display device produced utilizing the alignment key AK.

Furthermore, because the components of the capping layer CPL may include (e.g., be formed of) substantially the same materials and through substantially the same processes as the corresponding components in the display area DA, no separate process and material are desired or required, thereby enhancing manufacturing process efficiency.

A display device according to one or more embodiments is applicable to one or more suitable types (kinds) of electronic devices. In one or more embodiments, an electronic device includes the above-described display device and may further include other modules or devices having additional functions in addition to the display device.

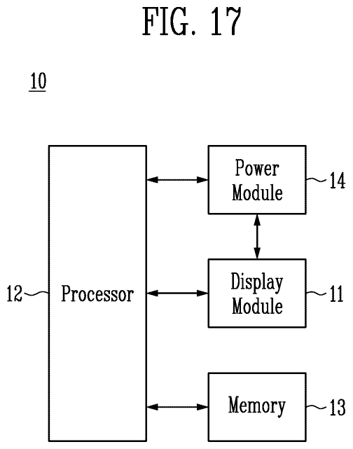

FIG. 17 is a block diagram of an electronic device according to one or more embodiments. Referring to FIG. 17, the electronic device 10 may include a display module 11, a processor 12, a memory 13, and a power module 14.

The processor 12 may include at least one of a central processing unit (CPU), an application processor (AP), a graphic processing unit (GPU), a communication processor (CP), an image signal processor (ISP), and a controller.

The memory 13 may store data and/or information that is utilized to operate the processor 12 and/or the display module 11. If (e.g., when) the processor 12 executes an application stored in the memory 13, image data signals and/or input control signals may be transferred to the display module 11. The display module 11 may process the provided signals and output image information on a display screen.

The power module 14 may include a power supply module, such as a power adapter and/or a battery device, and a power conversion module. The power conversion module converts power supplied by the power supply module and generates power to operate the electronic device 10.

At least one of the above-described components of the electronic device 10 may be included in the display device according to one or more embodiments as described above. In addition, in terms of functionality, some of the individual modules included in the electronic device 10 may be included in the display device and others may be provided separately from the display device. For example, the display module 11 is included in the display device, whereas the processor 12, the memory 13, and the power module 14 are not included in the display device and are instead provided separately in the electronic device 10.

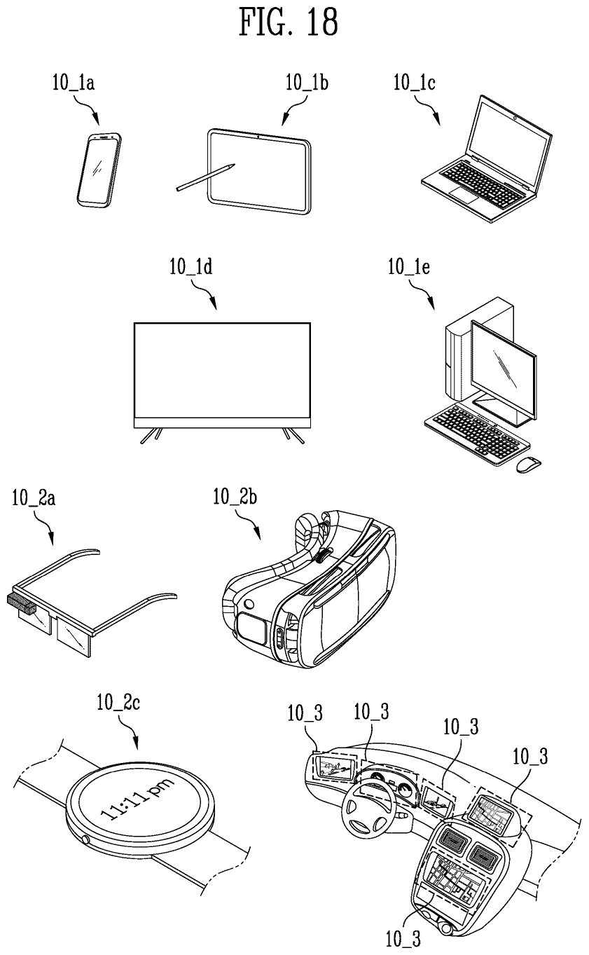

FIG. 18 shows schematic views of one or more suitable embodiments of an electronic device.

Referring to FIG. 18, one or more suitable types (kinds) of electronic devices to which embodiments of a display device are applied may include an electronic device to display images such as a smartphone 10_1a, a tablet PC 10_1b, a laptop computer 10_1c, a television (TV) 10_1d, and a desktop monitor 10_1e, a wearable electronic device including a display module such as smart glasses 10_2a, a head-mounted display (HMD) 10_2b, and a smart watch 10_2c, and an automotive electronic device 10_3 including a display module such as a center information display (CID) arranged at the instrument cluster, the center fascia, and the dashboard of a vehicle, and a room mirror display.

As described above, because a capping layer including inorganic material is arranged on an alignment key and a base layer in an entire alignment area, the capping layer may protect the base layer, and a reflectance of the alignment area where the alignment key and the base layer are arranged may be reduced. Accordingly, failure in recognition of the alignment key attributable to high reflectance during a manufacturing process may be reduced. As a result, the recognition rate of the alignment key is enhanced, which may improve the reliability of a display device manufactured utilizing the alignment key. Overall, with the existence of the alignment area including multiple alignment keys, the components of the display panel may be well-aligned and positioned during the manufacturing process, production yield and properties of the display panel may be increased and improved.

As used herein, the terms “substantially,” “about,” and similar terms are used as terms of approximation and not as terms of degree, and are intended to account for the inherent deviations in measured or calculated values that would be recognized by those of ordinary skill in the art. “About” or “approximately,” as used herein, is also inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ±30%, 20%, 10%, 5% of the stated value.

In the context of the present disclosure and unless otherwise defined, the terms “use,” “using,” and “used” may be considered synonymous with the terms “utilize,” “utilizing,” and “utilized,” respectively.

Any numerical range recited herein is intended to include all sub-ranges of the same numerical precision subsumed within the recited range. For example, a range of “1.0 to 10.0” is intended to include all subranges between (and including) the recited minimum value of 1.0 and the recited maximum value of 10.0, that is, having a minimum value equal to or greater than 1.0 and a maximum value equal to or less than 10.0, such as, for example, 2.4 to 7.6. Any maximum numerical limitation recited herein is intended to include all lower numerical limitations subsumed therein and any minimum numerical limitation recited in this specification is intended to include all higher numerical limitations subsumed therein. Accordingly, Applicant reserves the right to amend this specification, including the claims, to expressly recite any sub-range subsumed within the ranges expressly recited herein.

The electronic apparatus/device including the display device, the manufacturing apparatuses thereof, or any other relevant apparatuses/devices or components according to embodiments of the present disclosure described herein may be implemented utilizing any suitable hardware, firmware (e.g., an application-specific integrated circuit), software, or a combination of software, firmware, and hardware. For example, the various components of the device may be formed on one integrated circuit (IC) chip or on separate IC chips. Further, the various components of the device may be implemented on a flexible printed circuit film, a tape carrier package (TCP), a printed circuit board (PCB), or formed on one substrate. Further, the various components of the device may be a process or thread, running on one or more processors, in one or more computing devices, executing computer program instructions and interacting with other system components for performing the various functionalities described herein. The computer program instructions are stored in a memory which may be implemented in a computing device using a standard memory device, such as, for example, a random access memory (RAM). The computer program instructions may also be stored in other non-transitory computer readable media such as, for example, a CD-ROM, flash drive, or the like. Also, a person of skill in the art should recognize that the functionality of various computing devices may be combined or integrated into a single computing device, or the functionality of a particular computing device may be distributed across one or more other computing devices without departing from the scope of the embodiments of the present disclosure.

A person of ordinary skill in the art would appreciate, in view of the present disclosure in its entirety, that each suitable feature of the various embodiments of the present disclosure may be combined or combined with each other, partially or entirely, and may be technically interlocked and operated in various suitable ways, and each embodiment may be implemented independently of each other or in conjunction with each other in any suitable manner unless otherwise stated or implied.

The effects of the present disclosure are not limited by the foregoing, and other one or more suitable effects are anticipated herein.

While the spirit and scope of the present disclosure are described by detailed example embodiments, it should be noted that the above-described embodiments are merely descriptive and should not be considered limiting. It should be understood by those skilled in the art that one or more suitable changes, substitutions, and alternations may be made herein without departing from the scope of the disclosure as defined by the following claims and equivalents thereof.

The scope of the present disclosure and equivalents thereof are not limited by detailed descriptions of the present specification, and should be defined by the accompanying claims. Furthermore, all changes or modifications of the present disclosure derived from the meanings and scope of the claims, and equivalents thereof should be construed as being included in the scope of the present disclosure.

What is claimed is:

1. A display device, comprising:
a substrate;
a plurality of light emitting elements on the substrate and at a display area;
an alignment key on the substrate and at a portion of an alignment area of a non-display area enclosing the display area; and
a first capping layer covering an entirety of the alignment area and comprising an inorganic material.

2. The display device according to claim 1, further comprising a base layer between the substrate and the first capping layer and provided in the entirety of the alignment area other than the alignment key.

3. The display device according to claim 2,
wherein the base layer comprises:
a first base layer on the substrate; and
a second base layer between the first base layer and the first capping layer, and
wherein a reflectance of the first base layer is higher than a reflectance of the second base layer.

4. The display device according to claim 3,
wherein the first base layer comprises aluminum, and
wherein the second base layer comprises titanium nitride.

5. The display device according to claim 2, wherein the first capping layer comprises aluminum oxide.

6. The display device according to claim 5, wherein the display device further comprises:
a second capping layer on the first capping layer; and
a third capping layer on the second capping layer.

7. The display device according to claim 6,
wherein the second capping layer comprises acrylic resin, and
wherein the third capping layer comprises acrylic resin.

8. The display device according to claim 6, further comprising:
an encapsulation thin-film on the light emitting elements at the display area;
an adhesive layer on the encapsulation thin-film at the display area;
a color filter layer on the adhesive layer at the display area; and
a lens layer on the color filter layer at the display area.

9. The display device according to claim 8,
wherein the first capping layer comprises a material identical to the encapsulation thin-film,
wherein the second capping layer comprises a material identical to the adhesive layer, and
wherein the third capping layer comprises a material identical to the lens layer.

10. The display device according to claim 2, wherein the alignment key protrudes from an upper surface of the base layer.

11. The display device according to claim 1, wherein the alignment key comprises an inorganic material.

12. A method comprising:
forming light emitting elements on a substrate at a display area;
forming an alignment key on the substrate in a portion of an alignment area at a non-display area enclosing the display area; and
forming a capping layer covering an entirety of the alignment area and comprising an inorganic material,
wherein the method is a method of manufacturing a display device.

13. The method according to claim 12, further comprising, before the forming of the alignment key, forming a base layer on the substrate and comprising an opening defined in the portion of the alignment area.

14. The method according to claim 13, wherein the alignment key is formed at the opening, and protrudes from an upper surface of the base layer.

15. The method according to claim 13,
wherein the base layer comprises a first base layer and a second base layer,
wherein the forming of the base layer comprises:
forming a first base layer on the substrate;
forming a second base layer on the first base layer; and
forming the opening by patterning a portion of the first base layer and a portion of the second base layer, and
wherein a reflectance of a material forming the first base layer is higher than a reflectance of a material forming the second base layer.

16. The method according to claim 15,
wherein the first base layer comprises aluminum, and
wherein the second base layer comprises titanium nitride.

17. The method according to claim 13,
wherein the capping layer comprises first to third capping layers,
wherein the forming of the capping layer comprises:
forming the first capping layer on the base layer and comprising aluminum oxide;
forming the second capping layer on the first capping layer and comprising acrylic resin; and
forming the third capping layer on the second capping layer and comprising acrylic resin.

18. The method according to claim 17, further comprising, after the forming of the light emitting elements:
forming an encapsulation thin-film on the light emitting elements at the display area;
forming an adhesive layer on the encapsulation thin-film at the display area;
forming a color filter layer on the adhesive layer at the display area; and
forming a lens layer on the color filter layer at the display area.

19. The method according to claim 18,
wherein the first capping layer is formed concurrently with the encapsulation thin-film,
wherein the second capping layer is formed concurrently with the adhesive layer, and
wherein the third capping layer is formed concurrently with the lens layer.

20. An electronic device, comprising:
a processor to provide input image data; and
a display device to display an image based on the input image data,
wherein the display device comprises:
a substrate;
light emitting elements on the substrate and at a display area;
an alignment key on the substrate and at a portion of an alignment area of a non-display area enclosing the display area; and
a capping layer covering an entirety of the alignment area, and comprising an inorganic material.
